(19) United States
(12) Patent Application Publication
(10) Pub. No.: US 2014/0159055 A1
(43) Pub. Date: Jun. 12, 2014

(54) SUBSTRATES FOR SEMICONDUCTOR DEVICES

(71) Applicant: ELEMENT SIX LIMITED, Ballasalla, IM (US)

(72) Inventors: Richard Stuart Balmer, Berkshire (GB); Timothy Peter Mollart, Berkshire (GB); Christopher John Howard Wort, Oxfordshire (GB)

(21) Appl. No.: 14/097,429

(22) Filed: Dec. 5, 2013

Related U.S. Application Data
(60) Provisional application No. 61/736,402, filed on Dec. 12, 2012.

(30) Foreign Application Priority Data
Dec. 12, 2012 (GB) 1222352.5

(51) Int. Cl. H01L 21/02; H01L 29/16

(52) U.S. Cl. CPC H01L 21/02527; H01L 29/1602
USPC 257/77; 438/105

(57) ABSTRACT

A method of manufacturing a composite substrate for a semiconductor device, the method comprising:
depositing silicon on a surface of a synthetic diamond wafer; and
treating the synthetic diamond wafer to transform the deposited silicon into silicon carbide thus forming a layer of silicon carbide on the surface of the synthetic diamond wafer,
wherein the synthetic diamond wafer is selected from one of: a single crystal diamond wafer; and a polycrystalline CVD diamond wafer having a nucleation face and a growth face wherein the nucleation face comprises smaller diamond grains than the growth face, and
wherein if the synthetic diamond wafer is a polycrystalline CVD diamond wafer then the silicon carbide layer is formed on the growth face of the polycrystalline CVD diamond wafer.

### FIELD OF INVENTION

The present invention relates to the manufacture of substrates for semiconductor devices.

### BACKGROUND OF INVENTION

Optoelectronic, high power, and high frequency devices are increasingly being fabricated using wide band gap compound semiconductor materials such as gallium nitride, aluminium nitride, and silicon carbide. Such semiconductor materials are frequently grown heteroepitaxially in thin film form onto a suitable substrate which provides a lattice matched template for crystal growth. Typical substrates include sapphire, silicon carbide, and silicon. For semiconductor devices such as microwave amplifier circuits, the substrate should be electrically insulating for the device to function.

A well known problem in semiconductor devices is that of heat dissipation. High temperatures often limit the performance and/or lifetime of such devices. This is a particular problem in semiconductor devices which operate at high power density and/or high frequency such as microwave amplifiers, power switches and optoelectronic devices. It is therefore desirable to be able to spread any heat generated by component devices to reduce temperatures and thus improve device performance, increase lifetime, and/or increase power density. Accordingly, it is desirable to utilize a substrate material with a high thermal conductivity to spread the heat generated by a device and facilitating heat dissipation via a heat sink thus improving device performance, increasing lifetime, and/or enabling an increase in power density.

It is evident that there is a requirement for a low-cost, large area substrate with exceptional thermal properties for high power devices including microwave field effect transistors (FETs) and high power light emitting diodes and laser diodes (LEDs/LDs). Such devices are typically fabricated from III-Nitride epilayers grown on a foreign single crystal substrate such as sapphire (Al₂O₃), silicon carbide (SiC) or (111) orientated silicon (Si).

Semi-insulating silicon carbide (SiC) wafers (4H or 6H polytype) are commonly used as a substrate for high performance, high power gallium nitride (GaN) microwave field effect transistors because silicon carbide has a relatively high thermal conductivity (compared to sapphire) and a close lattice match to gallium nitride (3.5%) allowing high quality epilayers to be produced. However, silicon carbide is comparatively expensive compared to silicon and sapphire and has only recently become available in wafer diameters up to 6 inches (152 mm) at the time of writing this specification.

(111) oriented silicon wafers are also used as a substrate for gallium nitride microwave field effect transistors. The highest resistivity (111) oriented silicon (about 10⁴ Ω·cm) is readily available in wafer diameters up to at least 6 inches (152 mm) which is compatible with a semiconductor fabrication line. Such silicon wafers are also relatively cheap. However, the thermal conductivity of silicon wafers is poor when compared to silicon carbide and high resistivity silicon is lossy at RF frequencies.

Sapphire, (111)-silicon, and silicon carbide are commonly used as a substrate for high power gallium nitride light emitting diodes (LEDs) and laser diodes (LDs). However, although relatively low-cost, sapphire and silicon have a poorer thermal conductivity compared to silicon carbide which is expensive.

Diamond has unique properties as a heat spreading material, combining the highest room temperature thermal conductivity of any solid material, with high electrical resistivity and low dielectric loss when in an intrinsic undoped form. Thus diamond is utilized as a heat spreading substrate for semiconductor components in a number of high power density applications. The advent of large area polycrystalline diamond produced by a chemical vapour deposition (CVD) technique has expanded the applications for diamond heat spreaders via an increase in area and a reduction in cost. The majority of favourable thermal, dielectric and insulating properties of diamond are not dependent on the single crystal structure of naturally occurring or synthetic single crystal diamond material. Accordingly, polycrystalline CVD diamond wafers have been developed and are commercially available in sizes that enable them to be directly integrated with the fabrication processes of wide band gap semiconductors as a substrate material.

In light of the above, it is evident that for thin film compound semiconductor materials, an ability to integrate diamond as a carrier substrate could greatly improve thermal performance. For high power devices, the challenge is to position an active region of a device in as close proximity as possible to the heat spreading diamond substrate, since any intermediate carrier substrate material such as sapphire, silicon, or silicon carbide acts as a thermal barrier.

Compound semiconductor materials can be grown directly on a polycrystalline diamond substrate using, for example, a metal organic chemical vapour deposition (MOCVD) technique. However, semiconductor material grown in such a manner will itself be polycrystalline, the crystals being distributed over a range of crystallographic orientations relative to the plane of the substrate. Such a polycrystalline layer of semiconductor material will tend to have a lower charge mobility and thus will not provide the same performance as single crystal semiconductor material for many proposed applications, particularly those which require high charge (electron and/or hole) mobility characteristics such as a high electron mobility transistor (HEMT) used in microwave frequency amplifier circuits. As such, it is desirable to provide a method which allows the formation of a monocrystalline semiconductor layer or at least a better ordered polycrystalline semiconductor layer.

Two main approaches to solve the aforementioned problem have been proposed to date: (1) form a monocrystalline layer of silicon or silicon carbide on a polycrystalline diamond substrate and then epitaxially grow compound semiconductor material on the monocrystalline layer of silicon or silicon carbide layer; or (2) provide a substrate which comprises a compound semiconductor layer and grow polycrystalline diamond material on such a substrate. However, problems exist with both these approaches. Having regard to the first approach, the layer of silicon or silicon carbide acts as a thermal barrier to heat transfer from the compound semiconductor layer to the underlying diamond substrate. As such, it is desirable to make the layer of silicon or silicon carbide as thin as possible. Furthermore, since it is desirable for the silicon or silicon carbide layer to be monocrystalline to provide a monocrystalline surface on which a monocrystalline layer of compound semiconductor can be epitaxially grown, the thin silicon or silicon carbide layer cannot be formed by direct deposition on a polycrystalline diamond substrate as this will result in a polycrystalline layer of silicon or silicon carbide being formed. Accordingly, prior art documents have suggested methods for fabricating a diamond-compound semiconductor composite wafer which involve: growth of a CVD diamond layer on a monocrystalline silicon or silicon carbide substrate; thinning of the monocrystalline silicon or silicon carbide substrate to leave a thin layer of monocrystalline silicon or silicon carbide on the polycrystalline diamond; and then epitaxial growth of a monocrystalline compound semi-conductor on the thin layer of monocrystalline silicon or silicon carbide. Prior art documents which relate to various aspects of this approach include: U.S. Pat. No. 7,595,507; US 2010/0001293; US 2009/0272984; US 2006/0113545; U.S. Pat. No. 7,695,564; WO 2006/100559; and WO2011/161190.

Various problems exist with the aforementioned approaches which have prevented commercialization of such a process to date. For example, the thinning step can be time consuming and/or difficult to control in order to provide a very thin layer of monocrystalline silicon or silicon carbide over a polycrystalline diamond substrate. The thin layer of monocrystalline silicon or silicon carbide can be subject to polishing damage, cracking, and/or delamination such as via peeling. Even where etching is used in place of more conventional mechanical processing to achieving the thinning step cracking and/or delamination is still problematic. This is because as the layer of silicon or silicon carbide becomes very thin, the overall thermal expansion coefficient of the composite substrate is then dominated by the thicker diamond layer. Thermal expansion coefficient mismatches can then lead to stress-relieving cracking either in the thin silicon/silicon carbide layer or in an overlying layer of compound semiconductor material grown thereon. As such, although growth of diamond material on a silicon or silicon carbide substrate followed by thinning of the silicon or silicon carbide substrate would appear to be simple in principle, in practice stresses induced in the silicon or silicon carbide substrate during diamond growth and cooling making thinning of the silicon or silicon carbide substrate to produce a sufficiently thin layer of high quality silicon or silicon carbide exceedingly difficult in practice.

The second alternative approach, as mentioned previously, involves providing a substrate which comprises a compound semiconductor layer and growing polycrystalline diamond material on such a substrate. Prior art documents which relate to this approach include U.S. Pat. No. 7,595,507, U.S. Pat. No. 7,943,485, U.S. Pat. No. 8,283,189, and U.S. Pat. No. 8,283,672. Mismatches in thermal expansion coefficient can also be problematic using this approach. Furthermore, the harsh synthesis environment required to synthesize a diamond layer can damage the compound semiconductor material in the substrate thus degrading performance.

In both the aforementioned approaches the problems of thermal expansion coefficient mismatch can be alleviated to some extent by providing a very thin layer of diamond material. However, such very thin layers of diamond material have a lower thermal heat spreading capability.

In addition to the problems discussed above, one major drawback of both the aforementioned approaches is that the nucleation face of the diamond layer will inevitably be located proximate to the compound semiconductor layer with the growth face of the diamond layer being located distal to the compound semiconductor layer. This is problematic because the nucleation face of a layer of polycrystalline CVD diamond material has a much lower thermal conductivity than that of the growth face. The nucleation face can readily be distinguished from the growth face of polycrystalline CVD diamond material in that the grain size of the polycrystalline diamond material increases during growth such that the nucleation face comprises smaller grains and a larger number of grain boundaries while the growth face comprises larger grains with a smaller number of grain boundaries. As such, the growth face has a significantly higher thermal conductivity than the nucleation face. FIG. 1 illustrates how thermal conductivity of polycrystalline CVD synthetic diamond material increases on passing from a nucleation face of the polycrystalline CVD synthetic diamond material to a growth face of the polycrystalline CVD synthetic diamond material.

It should be appreciated that in light of the above, it would be desirable to provide a fabrication process in which the higher thermal conductivity growth face is placed closest to the compound semiconductor material in order to more effectively function as a heat spreader. However, the above-described fabrication methods inevitably result in the nucleation face of the diamond material being located closest to the compound semiconductor material. This significantly reduces the heat spreading performance advantages of integrating diamond material into a composite semiconductor wafer. While various prior art documents as discussed above have focussed on the issue of thinning a monocrystalline silicon or silicon carbide layer prior to compound semiconductor growth thereon such that the diamond material is located close to the compound semiconductor material, or controlling diamond growth conditions such that a diamond layer can be grown on a compound semiconductor substrate while minimizing damage of the compound semiconductor during diamond growth, none of these documents have recognized that an inherent problem with the proposed fabrication routes is that the diamond material will effectively be the wrong-way around relative to the compound semiconductor material for optimal heat spreading performance.

Further background references relating to synthetic diamond, silicon carbide, and gallium nitride growth include the following:
“Epitaxial 3C—SiC nanocrystal formation at the SiO2/Si interface by combined carbon implantation and annealing in CO atmosphere” B Pecz et al, J. Appl. Phys. 105 (2009) 083508-1;
“Diamond formation in cubic silicon carbide” B Pecz et al, APL 82 (2003) 46;
“Ion beam synthesis of epitaxial silicon carbide in nitrogen-implanted diamond” V Heera et al, APL 77 (2000) 226;
“Ion beam synthesis of graphite and diamond in silicon carbide” V Heera et al, APL 76 (2000) 2847;
“Heteroepitaxial growth of highly orientated diamond on cubic silicon carbide” H Kawarada et al, J. Appl. Phys. 81 (1997) 3490; and
“SiC rapid thermal carbonization of the (111)Si semiconductor-on-insulator structure and subsequent metalorganic chemical vapour deposition of GaN” A J Steckl et al, APL 69 (1996) 2264.

It is an aim of certain embodiments of the present invention to provide a method of forming a composite diamond-compound semiconductor wafer in which higher thermal conductivity diamond material is located proximal to the compound semiconductor.

### SUMMARY OF INVENTION

According to a first aspect of the present invention there is provided a method of manufacturing a composite substrate for a semiconductor device, the method comprising:
depositing silicon on a surface of a synthetic diamond wafer; and
treating the synthetic diamond wafer to transform the deposited silicon into silicon carbide thus forming a layer of silicon carbide on the surface of the synthetic diamond wafer,
wherein the synthetic diamond wafer is selected from one of: a single crystal diamond wafer; and a polycrystalline CVD diamond wafer having a nucleation face and a growth face wherein the nucleation face comprises smaller diamond grains than the growth face, and
wherein if the synthetic diamond wafer is a polycrystalline CVD diamond wafer then the silicon carbide layer is formed on the growth face of the polycrystalline CVD diamond wafer.

Accordingly to a further aspect of the present invention there is provided a composite substrate for a semiconductor device, the composite substrate comprising:
a synthetic diamond wafer; and
a layer of silicon carbide on a surface of the synthetic diamond wafer,
wherein the synthetic diamond wafer is a polycrystalline CVD diamond wafer having a nucleation face and a growth face wherein the nucleation face comprises smaller diamond grains than the growth face, and
wherein the silicon carbide layer is formed on the growth face of the polycrystalline CVD diamond wafer.

### BRIEF DESCRIPTION OF THE DRAWINGS

For a better understanding of the present invention and to show how the same may be carried into effect, embodiments of the present invention will now be described by way of example only with reference to the accompanying drawings, in which:

FIGS. 1A and 1B illustrate how thermal conductivity of polycrystalline CVD synthetic diamond material increases on passing from a nucleation face of the polycrystalline CVD synthetic diamond material to a growth face of the polycrystalline CVD synthetic diamond material;

FIG. 2 illustrates a composite substrate comprising a polycrystalline CVD diamond wafer, a thin layer of silicon carbide disposed on the growth face of the polycrystalline CVD diamond wafer, and compound semiconductor material disposed on the thin layer of silicon carbide; and

FIG. 3 illustrates a similar composite substrate to that shown in FIG. 2 but which utilizes a single crystal CVD diamond wafer rather than a polycrystalline CVD diamond wafer.

### DETAILED DESCRIPTION OF CERTAIN EMBODIMENTS

The present invention is based on the realization that a major problem of prior art techniques for integrating diamond heat spreading substrates into compound semiconductor devices is that the highest thermal conductivity diamond material is not located sufficiently close to the heat generating semiconductor layers. As such, the present invention proposes alternate methods of integrating the diamond material into semiconductor device structures such that the highest thermal conductivity diamond material is located proximal to the heat generating semiconductor layers. In this regard, the provision of a layer of silicon carbide and the provision of lower thermal conductivity diamond material at the thermal interface region can act as a thermal barrier to heat flow from an overlying device to an underlying diamond heat spreading wafer thus increasing thermal barrier resistance (TBR). Embodiments of the present invention lower thermal barrier resistance and increase heat spreading capability by providing a method of forming a very thin layer of silicon carbide on higher thermal conductivity diamond material thus reducing the thermal barrier resistance at the thermal interface region between an overlying device and an underlying diamond heat spreading wafer.

As described in the summary of invention section, according to a first aspect of the present invention there is provided a method of manufacturing a composite substrate for a semiconductor device, the method comprising:
depositing silicon on a surface of a synthetic diamond wafer; and
treating the synthetic diamond wafer to transform the deposited silicon into silicon carbide thus forming a layer of silicon carbide on the surface of the synthetic diamond wafer,
wherein the synthetic diamond wafer is selected from one of: a single crystal diamond wafer; and a polycrystalline CVD diamond wafer having a nucleation face and a growth face wherein the nucleation face comprises smaller diamond grains than the growth face, and
wherein if the synthetic diamond wafer is a polycrystalline CVD diamond wafer then the silicon carbide layer is formed on the growth face of the polycrystalline CVD diamond wafer.

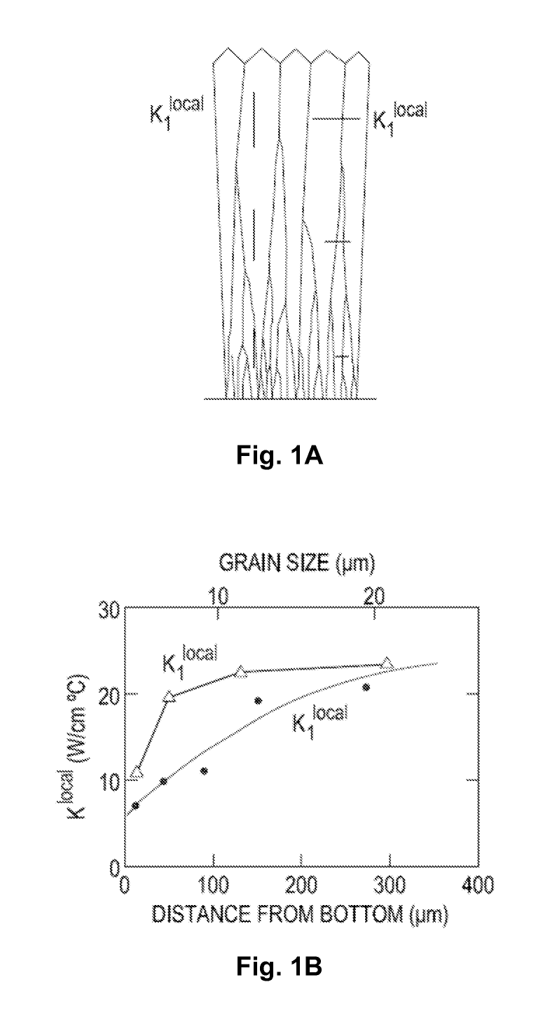

For the polycrystalline CVD diamond wafer option, the aforementioned process results in a thin layer of silicon carbide disposed on the growth face of a polycrystalline CVD diamond wafer. As illustrated in FIGS. 1A and 1B, the thermal conductivity of a polycrystalline CVD synthetic diamond material increases on passing from a nucleation face of the polycrystalline CVD synthetic diamond material to a growth face of the polycrystalline CVD synthetic diamond material. The presently proposed method thus provides a way of treating the growth face such that it is adapted for semiconductor growth thereon. The process has two major advantageous over prior art techniques: (1) higher thermal conductivity synthetic diamond material can be located at the thermal interface region; and (2) the layer of silicon carbide can be made thinner (e.g. a few atomic monolayers thick) without problems of cracking via a thinning process. Both these effects result in a reduction in thermal barrier resistance at the thermal interface between the diamond wafer and overlying compound semiconductor layers.

In addition to the above, it has also been recognized that a similar treatment process can be applied to a single crystal diamond wafer. In this instance, synthetic single crystal diamond, such as high purity single crystal CVD or HPHT synthetic diamond material, has a generally uniform thermal conductivity which is higher than polycrystalline CVD diamond material and thus it is not required that the treatment is performed on the growth face of a single crystal diamond wafer.

Both the aforementioned techniques result in a very thin layer of silicon carbide disposed on the surface of a diamond wafer such that the layer of diamond material immediately under the silicon carbide coating is of higher thermal conductivity than a nucleation face of a polycrystalline CVD diamond wafer. A semiconductor material subsequently grown over the silicon carbide coating will thus be located close to higher thermal conductivity diamond material and thus the diamond material will function more efficiently as a heat spreader. As such, both the aforementioned options provide an improvement over the prior art methods of integrating a diamond wafer heat spreader into a semiconductor device structure which inherently require the nucleation face of a polycrystalline CVD diamond wafer to be located closest to the active semiconductor component layers.

Furthermore, both the aforementioned methods avoid the requirement to grow the diamond material on a silicon or silicon carbide wafer which is then subsequently thinned down prior to growth of active semiconductor layers thereon. This avoids problems of stress related cracking of the silicon or silicon carbide layer on thinning and also allows the diamond wafer to be grown thicker without exacerbating problems of stress related cracking which occur in the prior art methods which involve diamond wafer growth on a silicon or silicon carbide wafer followed by thinning of the silicon or silicon carbide wafer. As such, the diamond wafer may have a thickness equal to or greater than 50 μm, 75 μm, 100 μm, 150 μm, 200 μm, 250 μm, or 300 μm, and optionally less than 1 mm.

When silicon carbide is formed in the described manner on a polycrystalline CVD diamond wafer it will be noted that the resultant silicon carbide will have registration to the diamond grains and thus will be polycrystalline. However, recent evidence has shown that ordered compound semiconductor growth can be achieved on such polycrystalline silicon carbide surfaces. Furthermore, if a single crystal silicon wafer is pressed against the polycrystalline CVD diamond wafer and heated to form the silicon carbide layer, the ordered state of the single crystal silicon wafer may impart some degree of order to the resultant silicon carbide layer.

Alternatively, it is possible to impart some crystal order to the silicon carbide layer by using a single crystal diamond wafer rather than a polycrystalline CVD diamond wafer. Accordingly, an alternative embodiment provides a corresponding method but using a single crystal diamond wafer rather than a polycrystalline CVD diamond wafer. If a single crystal diamond wafer is utilized rather than a polycrystalline CVD diamond wafer then there is no or little asymmetry in the thermal conductivity between the nucleation face and the growth face of the material and thus it is not critical to form the silicon carbide layer on the growth face of the material. However, it has been recognized that the proposed methods for forming a thin silicon carbide layer on the growth face of a polycrystalline CVD diamond wafer can be equally well applied to a single crystal diamond wafer to avoid the problems associated with prior art methods of integrating a diamond heat spreading wafer into a compound-semiconductor device structure.

The heat treatment step may be performed during the silicon deposition step or after silicon deposition. This will depend on the specific method utilized for depositing and heating the silicon deposited on the surface of the diamond wafer. For example, the silicon deposition step may comprise one of: ion beam implantation of silicon ions into the synthetic diamond wafer; sputtering a film of silicon onto the synthetic diamond wafer, chemical vapour deposition of silicon (e.g. using silane) onto the synthetic diamond wafer; or merely pressing a wafer of silicon (optionally a single crystal silicon wafer) against the synthetic diamond wafer.

The deposition and heat treating steps are preferably performed under non-oxidizing conditions, e.g. under vacuum or under a reducing atmosphere. This is advantageous to prevent oxidation of silicon completing with silicon carbide formation. Alternatively, or additionally, the silicon may also be pre-treated to remove native silicon oxide prior to the heat treatment.

Optionally, after formation of the silicon carbide layer the surface of the layer is cleaned prior to growth of a compound semiconductor thereon. Cleaning will be required for certain silicon deposition processes where excess silicon remains on the surface of the diamond wafer after silicon carbide formation. However, it is possible that with well controlled ion beam silicon implantation or CVD deposition processes a silicon carbide layer may be formed without any excess residual silicon remaining on the growth face of the diamond material thereby negating the requirement for a cleaning step. For example, in one arrangement the silicon carbide layer can be formed within a CVD chamber and then process gases changed to transition into compound semiconductor deposition thereon within the same CVD chamber thus providing an in-situ CVD growth method for fabricating both the silicon carbide layer and the overlying compound semiconductor layer or layers. For example, the silicon carbide layer may be formed within a CVD chamber using a silane treatment or silicon deposition using silane and then the CVD process gas may be switches to those known for compound semiconductor CVD deposition processes such as those for fabricating nitride layers.

Using the methodology as described herein it is possible to fabricate a composite substrate for a semiconductor device, the composite substrate comprising:
a synthetic diamond wafer; and
a layer of silicon carbide on a surface of the synthetic diamond wafer,
wherein the synthetic diamond wafer is one of: a single crystal diamond wafer; and a polycrystalline CVD diamond wafer having a nucleation face and a growth face wherein the nucleation face comprises smaller diamond grains than the growth face, and
wherein if the synthetic diamond wafer is a polycrystalline CVD diamond wafer then the silicon carbide layer is formed on the growth face of the polycrystalline CVD diamond wafer.

As such, according to one configuration the synthetic diamond wafer may be a polycrystalline CVD diamond wafer and the silicon carbide layer is formed on the growth face of the polycrystalline CVD diamond wafer. Alternatively, the synthetic diamond wafer may be a single crystal diamond wafer. In this case it is preferable that the single crystal diamond wafer is a single crystal CVD diamond wafer as it is possible to achieve higher thermal conductivities using such wafers when compared to other types of diamond material such as single crystal HPHT diamond material. Further still, ideally the single crystal diamond wafer is a {111} oriented single crystal CVD diamond wafer. Such an oriented diamond wafer can be used in conjunction with ion beam synthesis of silicon carbide to form a crystalline layer of 3C—SiC domains which are epitaxially aligned to the surrounding diamond lattice.

The composite substrate may further comprise a compound semiconductor on the layer of silicon carbide disposed on the synthetic diamond wafer. For example, the compound semiconductor comprises one or more nitride layers. The one or more nitride layers may include a layer of gallium nitride, a layer of aluminium nitride, and/or a layer of aluminium gallium nitride. Such nitride semiconductor layers are useful as wide band-gap materials for power electronics applications where high temperatures can be generated in the semiconductor layers requiring very efficient heat spreading as provided by embodiments of the present invention. For example, an aluminium or aluminium gallium nitride buffer layer may be deposited on the silicon carbide layer followed by a layer of gallium nitride.

In order to achieve good thermal heat spreading performance the silicon carbide layer should be thin such that the thermal barrier resistance between the overlying compound semiconductor and the underlying diamond material is low. For example, the silicon carbide layer may have a thickness no more than 10 μm, 5 μm, 3 μm, 1 μm, 100 nm, 50 nm, 30 nm, 20 nm, or 5 nm. However, the silicon carbide layer should be sufficiently thick to provide a uniform and coherent layer on which the compound semiconductor material can be grown with sufficient crystal order to achieve required device performance. For example, the layer of silicon carbide may have a thickness sufficient to ensure at least a coherent monolayer of silicon carbide. This may involve the fabrication of several atomic monolayers of silicon carbide. The layer may have a thickness of at least 0.01 nm, 0.1 nm, or 1 nm. Furthermore, the silicon carbide layer should have a uniform thickness to provide a uniform surface on which the compound semiconductor material is grown. For example, the silicon carbide layer may have a thickness which varies by no more than 10 μm, 5 μm, 1 μm, 500 nm, 200 nm, 100 nm, 50 nm, 10 nm, 5 nm or 1 nm over an area greater than or equal to 50%, 60%, 70%, 80% or 90% of a total surface area of the silicon carbide layer.

In relation to the above, it is advantageous for the surface of the synthetic diamond wafer has a very low surface roughness. In this case, a very thin silicon carbide layer can be conformal to the diamond surface and it is more easy to form a coherent, high quality, low surface roughness silicon carbide surface on such a low roughness diamond surface. For example, the synthetic diamond wafer may be processed to have a surface roughness R_{q} of no more 10 nm, 5 nm, or 1 nm prior to formation of the layer of silicon carbide thereon. Such a low roughness diamond surfaces may be fabricated using techniques such as lapping, polishing, and etching.

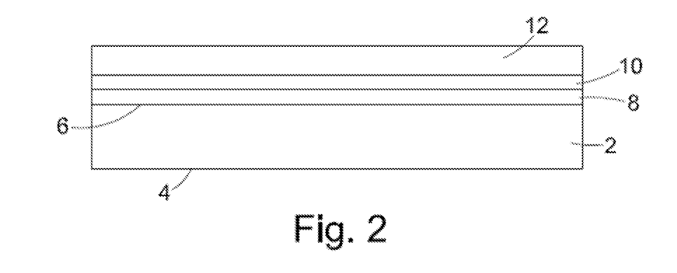

FIG. 2 illustrates a composite substrate configuration according to an embodiment of the present invention. The composite substrate comprises a polycrystalline CVD diamond wafer 2 comprising a nucleation face 4 and a growth face 6. A thin layer of silicon carbide 8 is disposed on the growth face 6 of the polycrystalline CVD diamond wafer 2. A buffer layer of aluminium nitride 10 is disposed on the silicon carbide layer 8 and a layer of gallium nitride 12 is disposed on the aluminium nitride buffer layer 10.

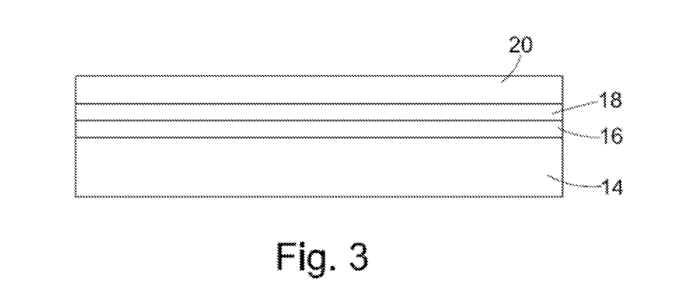

FIG. 3 illustrates a similar composite substrate configuration but which utilizes a single crystal CVD diamond wafer. The composite substrate comprises a single crystal CVD diamond wafer 14, a thin layer of silicon carbide 16 disposed on the single crystal CVD diamond wafer, a buffer layer of aluminium nitride 18 is disposed on the silicon carbide layer 16, and a layer of gallium nitride 20 is disposed on the aluminium nitride buffer layer 18.

While this invention has been particularly shown and described with reference to preferred embodiments, it will be understood to those skilled in the art that various changes in form and detail may be made without departing from the scope of the invention as defined by the appendant claims.

1. A method of manufacturing a composite substrate for a semiconductor device, the method comprising:
depositing silicon on a surface of a synthetic diamond wafer; and
treating the synthetic diamond wafer to transform the deposited silicon into silicon carbide thus forming a layer of silicon carbide on the surface of the synthetic diamond wafer,
wherein the synthetic diamond wafer is selected from one of: a single crystal diamond wafer; and a polycrystalline CVD diamond wafer having a nucleation face and a growth face wherein the nucleation face comprises smaller diamond grains than the growth face, and
wherein if the synthetic diamond wafer is a polycrystalline CVD diamond wafer then the silicon carbide layer is formed on the growth face of the polycrystalline CVD diamond wafer.

2. A method according to claim 1, wherein the treating step for transforming silicon into silicon carbide on the surface of the synthetic diamond wafer is performed during the silicon deposition step or after silicon deposition.

3. A method according to claim 1, wherein the treating step comprises a heat treatment to transform silicon into silicon carbide on the surface of the synthetic diamond wafer.

4. A method according to claim 1, wherein the silicon deposition step comprises one of:
ion beam implantation of silicon ions into the synthetic diamond wafer;
sputtering a film of silicon onto the synthetic diamond wafer;
chemical vapour deposition of silicon onto the synthetic diamond wafer; or
pressing a wafer of silicon against the synthetic diamond wafer.

5. A method according to claim 3, wherein either or both of the deposition and heat treating steps are performed under non-oxidizing conditions.

6. A method according to claim 1, wherein the silicon is pre-treated to remove native silicon oxide prior to the heat treatment step.

7. A method according to claim 1, wherein the deposition step comprises chemical vapour deposition of silicon using silane.

8. A method according to claim 1, wherein the deposition step comprises pressing a single crystal wafer of silicon against the synthetic diamond wafer.

9. A method according to claim 1, wherein after formation of the silicon carbide layer a surface of the silicon carbide layer is cleaned.

10. A method according to claim 1, further comprising:
growing a compound semiconductor on the layer of silicon carbide disposed on the synthetic diamond wafer.

11. A method according to claim 10, wherein the compound semiconductor and the silicon carbide layer are fabricated in-situ within the same chemical vapour deposition reactor.

12. A method according to claim 1, wherein the surface of the synthetic diamond wafer is processed to have a surface roughness R_{q} of no more 10 nm, 5 nm, or 1 nm prior to formation of the layer of silicon carbide thereon.

13. A composite substrate for a semiconductor device, the composite substrate comprising:
a synthetic diamond wafer; and
a layer of silicon carbide on a surface of the synthetic diamond wafer,
wherein the synthetic diamond wafer is a polycrystalline CVD diamond wafer having a nucleation face and a growth face wherein the nucleation face comprises smaller diamond grains than the growth face, and
wherein the silicon carbide layer is formed on the growth face of the polycrystalline CVD diamond wafer.

14. A composite substrate according to claim 13, further comprising:
a compound semiconductor on the layer of silicon carbide disposed on the synthetic diamond wafer.

15. A composite substrate according to claim 14, wherein the compound semiconductor comprises one or more nitride layers.

16. A composite substrate according to claim 15, wherein the one or more nitride layers includes a layer of aluminium nitride or aluminium gallium nitride.

17. A composite substrate according to claim 15, wherein the one or more nitride layers includes a layer of gallium nitride.

18. A composite substrate according to claim 13, wherein the silicon carbide layer has a thickness no more than 10 μm, 5 μm, 3 μm, 1 μm, 100 nm, 50 nm, 30 nm, 20 nm, or 5 nm.

19. A composite substrate according to claim 13, wherein the silicon carbide layer has a thickness which varies by no more than 10 μm, 5 μm, 1 μm, 500 nm, 200 nm, 100 nm, 50 nm, 10 nm, or 5 nm over an area greater than or equal to 50%, 60%, 70%, 80% or 90% of a total surface area of the silicon carbide layer.

20. A composite substrate according to claim 13, wherein the synthetic diamond wafer has a thickness equal to or greater than 50 μm, 75 μm, 100 μm, 150 μm, 200 μm, 250 μm, or 300 μm.
